(19) United States
(12) Patent Application Publication
(10) Pub. No.: US 2025/0125310 A1
(43) Pub. Date: Apr. 17, 2025

(54) SEMICONDUCTOR PACKAGE STRUCTURES

(71) Applicant: Yangtze Memory Technologies Co., Ltd., Wuhan (CN)

(72) Inventors: Daiyu LI, Wuhan (CN); Mingkang ZHANG, Wuhan (CN); Chengbao ZHOU, Wuhan (CN); Min WEN, Wuhan (CN); Zhen PAN, Wuhan (CN); Shu WU, Wuhan (CN)

(21) Appl. No.: 18/518,416

(22) Filed: Nov. 22, 2023

Related U.S. Application Data
(63) Continuation of application No. PCT/CN2023/124261, filed on Oct. 12, 2023.

(51) Int. Cl. H01L 25/065; H01L 23/00; H01L 23/498; H01L 25/00

(52) U.S. Cl. CPC H01L 25/0657; H01L 23/49816; H01L 23/49838; H01L 24/08; H01L 24/16; H01L 24/48; H01L 24/73; H01L 25/50; H01L 2224/08145; H01L 2224/08225; H01L 2224/16145; H01L 2224/16227; H01L 2224/48147; H01L 2224/48225; H01L 2224/73207; H01L 2224/73257; H01L 2225/06506; H01L 2225/0651; H01L 2225/06517; H01L 2924/1436

(57) ABSTRACT

In some aspects, a package structure includes a substrate and semiconductor devices stacked over the substrate. The semiconductor devices are stacked along a first direction, and at least one of the semiconductor devices comprises one or more pads located on a side surface of the at least one of the semiconductor devices.

### CROSS-REFERENCE TO RELATED APPLICATIONS

This application is a continuation of International Application No. PCT/CN2023/124261, filed on Oct. 12, 2023, the disclosure of which is hereby incorporated by reference in its entirety.

### TECHNICAL FIELD

The present disclosure relates to semiconductor package structures and fabrication methods thereof.

### BACKGROUND

Semiconductor packaging refers to the process of enclosing and protecting semiconductor dies or chips after they have been manufactured on semiconductor wafers. This packaging provides a means to connect the dies or chips to a device that they will power, such as a computer, smartphone, or countless other electronic gadgets. The choice of packaging technique is based on several factors including the intended application, power consumption, heat generation, and desired footprint. As technology continues to advance, smaller, more efficient, and more functional packaging solutions are desirable.

### SUMMARY

In one aspect, a package structure includes a substrate and semiconductor devices stacked over the substrate. The semiconductor devices are stacked along a first direction. At least one of the semiconductor devices includes one or more pads located on a side surface of the at least one of the semiconductor devices.

Particular implementations may include one or more of the following features.

In some embodiments, the semiconductor devices are aligned along one side of the semiconductor devices.

In some embodiments, at least one of the semiconductor devices includes a side surface parallel to the first direction, and one or more pads of the at least one of the semiconductor devices are disposed on the side surface.

In some embodiments, at least one of the semiconductor devices includes a side surface having an acute angle with the first direction, and one or more pads of the at least one of the semiconductor devices are disposed on the side surface.

In some embodiments, at least one of the semiconductor devices includes a side surface having an acute angle with the first direction, and one or more pads of the at least one of the semiconductor devices are disposed in a recessed structure at the side surface.

In some embodiments, the substrate includes one or more pads, and the package structure further includes bond wires coupling pads of the semiconductor devices and the substrate. In such embodiments, the package structure further includes one or more contacting structures on the substrate, wherein the one or more contacting structures are coupled to a neighboring semiconductor die.

In some embodiments, the package structure further includes a coupling structure parallel to the first direction, and the coupling structure is configured to couple the semiconductor devices and the substrate. In such embodiments, the coupling structure includes contacting structures coupled to pads of the semiconductor devices and the substrate.

In some embodiments, at least one of the semiconductor devices includes one or more sealing structures. In such embodiments, the at least one of the semiconductor devices further includes one or more wires routed through and isolated from the one or more sealing structures. The one or more wires are coupled to one or more pads of the at least one of the semiconductor devices.

In another aspect, a coupling structure includes first contacting structures on a first side surface of the coupling structure, and second contacting structures on a second side surface of the coupling structure, wherein the second side surface is perpendicular to the first side surface.

Particular implementations may include one or more of the following features.

In some embodiments, the first contacting structures are coupled to semiconductor devices, and the second contacting structures are coupled to a substrate.

In some embodiments, the coupling structure includes a circuit layer coupled to the first contacting structures and the second contacting structures.

In another aspect, a method for manufacturing a package structure includes: forming a coupling structure on a substrate, wherein the coupling structure is perpendicular and coupled to the substrate, the coupling structure includes first contacting structures on a first side surface of the coupling structures and second contacting structures on a second side surface of the coupling structure, and the second side surface is perpendicular to the first side surface; stacking semiconductor devices over the substrate; and bonding the coupling structure to the semiconductor devices.

Particular implementations may include one or more of the following features.

In some embodiments, the method further includes forming one or more pads on a side surface of at least one of the semiconductor devices.

In some implementations, forming the one or more pads on the side surface of the at least one of the semiconductor devices includes: forming a semiconductor layer, wherein the semiconductor layer includes one or more sealing structures; forming one or more wires and one or more pads in the semiconductor layer, wherein the one or more wires are routed through and isolated from the one or more sealing structures, and the one or more wires are coupled to the one or more pads; and removing a portion of the semiconductor layer to expose the one or more pads.

In some implementations, forming the one or more pads on the side surface of the at least one of the semiconductor devices includes: forming one or more wires at a surface of a first semiconductor layer, wherein the one or more wires are routed through and isolated from one or more sealing structures in the first semiconductor layer; forming a second semiconductor layer over the surface of the first semiconductor layer to form a stacked layer; forming the one or more pads in the stacked layer, wherein the one or more wires are coupled to the one or more pads; and removing a portion of the stacked layer to expose the one or more pads.

In some implementations, the substrate includes one or more pads. Forming the coupling structure on the substrate includes bonding one or more of the second contacting structures of the coupling structure to the one or more pads of the substrate. Bonding the coupling structure to the semiconductor devices comprises bonding one or more of the first contacting structures of the coupling structure to the one or more pads of the at least one of the semiconductor devices.

The details of one or more implementations of the subject matter of this disclosure are set forth in the accompanying drawings and the description below. Other features, aspects, and advantages of the subject matter will become apparent from the description, the drawings, and the claims.

### BRIEF DESCRIPTION OF THE DRAWINGS

FIG. 1 shows a schematic diagram of an example package structure, in accordance with some embodiments of the present disclosure.

FIG. 2 shows a schematic diagram of an example semiconductor die, in accordance with some embodiments of the present disclosure.

FIG. 3 shows a schematic diagram of an example package structure, according to some embodiments of the present disclosure.

FIG. 4 shows a schematic diagram of an example package structure, according to some embodiments of the present disclosure.

FIG. 5 shows a schematic diagram of an example semiconductor die, according to some embodiments of the present disclosure.

FIG. 6 shows a schematic diagram of an example semiconductor die, according to some embodiments of the present disclosure.

FIG. 7 shows an example process of manufacturing a semiconductor die, according to some embodiments of the present disclosure.

FIG. 8 shows another example process of manufacturing a semiconductor die, according to some embodiments of the present disclosure.

FIG. 9 shows an example process of manufacturing a package structure, according to some embodiments of the present disclosure.

FIG. 10 shows another example process of manufacturing a package structure, according to some embodiments of the present disclosure.

FIG. 11 shows a schematic diagram of an example coupling structure, according to some embodiments of the present disclosure.

FIG. 12 shows a flowchart of an example process of manufacturing a package structure, in accordance with some embodiments of the present disclosure.

Like reference numbers and designations in the various drawings indicate like elements.

### DETAILED DESCRIPTION

Packaging semiconductor chips or dies is a critical step in the semiconductor manufacturing process. The primary purpose of packaging is to protect the delicate semiconductor chips or dies and provide a means for them to connect to external devices or systems. In some cases, semiconductor chips or dies are stacked to achieve improved performance, reduced power consumption, and potentially reduced costs. Example methods of stacking semiconductor chips or dies can include wire bonding, though-silicon vias (TSVs), flip-chip stacking, package-on-package (PoP), wafer-on-wafer stacking, etc. The choice of stacking method can depend on various factors including the intended application, costs, thermal considerations, and performance requirements.

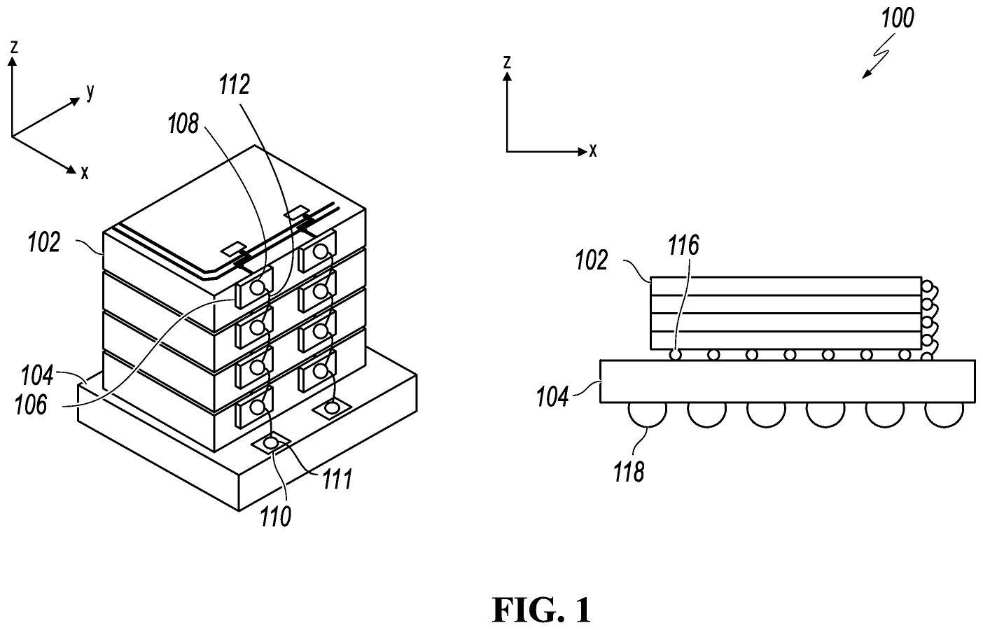

FIG. 1 shows a schematic diagram of an example package structure 100, in accordance with some embodiments of the present disclosure. As shown, package structure 100 includes multiple semiconductor devices 102 stacked over substrate 104. Note that package structure 100 is shown to include four semiconductor devices 102 for illustratively purpose only. In some examples, package structure 100 can have any suitable number of semiconductor devices 102, such as 5, 10, or 100, based on factors including technology constraints, thermal considerations, signal integrity and interferences, physical size and application, costs and yields, reliability concerns, etc.

In some embodiments, a semiconductor device 102 comprises a semiconductor die. In some embodiments, a semiconductor device 102 comprises a semiconductor chip.

In some examples, a semiconductor device 102 can include a semiconductor material such as silicon, germanium (Ge), gallium arsenide (GaAs), silicon germanium (SiGe), gallium Nitride (GaN), or silicon carbide (SiC).

In some embodiments, the size and shape of a semiconductor device 102 vary based on its function, the complexity of the integrated circuit, and the manufacturing technology used. In some examples, a semiconductor device 102 can be several centimeters in width. In some examples, a semiconductor device 102 can be a few millimeters across. In some examples, a semiconductor device 102 can be rectangular or square in shape. In some examples, a semiconductor device 102 can have an irregular shape to fit specific packages or devices. In some examples, a semiconductor device 102 can have rounded corners.

In some embodiments, a semiconductor device 102 includes an integrated circuit. In some examples, the integrated circuit of semiconductor device 102 can include one or more of the following: a digital circuit, am analog circuit, a mixed-signal circuit, a power management circuit, a specialized circuit, a communication interface, a microcontroller, a microprocessor, or an input/output (I/O) module, etc. In some examples, a semiconductor device 102 can include a non-volatile storage device, such as a NAND memory, or a volatile storage device, such as a dynamic random access memory (DRAM).

In some embodiments, a semiconductor device 102 includes one or more pads 106. In the shown example, each semiconductor device 102 includes two pads 106. Note that each semiconductor device 102 is shown to include two pads 106 for illustratively purpose only. In some examples, a semiconductor device 102 can include any suitable number of pads 106, such as 1, 3, or 5.

In some embodiments, pads 106 are configured to provide electrical connection between semiconductor devices 102. In some embodiments, pads 106 are configured to provide electrical connection from a semiconductor device 102 to other components of package structure 100 or external devices or systems. In some embodiments, a pad 106 includes a conductive layer to facilitate soldering and improve connection reliability. In some examples, a pad 106 can include a metal layer such as copper layer. In some examples, a pad 106 can include a metal layer coated with a thin layer of solder, such as gold, to prevent oxidation and improve solderability.

In some embodiments, the size and shape of a pad 106 vary based on its intended application, the design rules, and the manufacturing process. In some examples, a pad 106 can be square or rectangular in shape. In some examples, a pad 106 can have a special or customized shape to accommodate thermal or electrical requirements. In some examples, the size and shape of a pad 106 can be configured to match a solder ball or bump that is bonded to the pad 106.

In some embodiments, substrate 104 is configured to provide a mechanical support and an electrical function for the device structures, such as semiconductor devices 102, built upon it. In some examples, substrate 104 can act as an intermediary, providing electrical interconnections between semiconductor devices 102 and the external environment, such as a circuit board. In some examples, substrate 104 can include multiple layers of conductive traces to route signals to and from semiconductor devices 102, to facilitate connections to the outside world through pins, solder balls, or pads. In some examples, substrate 104 can include a ceramic or organic material such as FR-4 (a glass-reinforced epoxy laminate material), The choice of material of substrate 104 can depend on various factors, including thermal performance, electrical performance, and cost considerations.

In the shown example, substrate 104 includes two pads 110. In some embodiments, pads 110 are similar to pads 106. Accordingly, some descriptions of pads 110 are omitted here for brevity.

In some embodiments, semiconductors devices 102 and substrate 104 are interconnected using wire bonding, such as ball bonding or wedge boding. In an example ball bonding process, a solder ball can be first created at a wire's end by melting it with an electric flame-off, then pressed onto a bonding pad on a semiconductor die to form a bond. In an example wedge bonding process, a wire can be directly bonded to a bonding pad using a wedge-shaped tool.

In the shown example, semiconductor devices and substrate 104 are interconnected using ball bonding. In the shown example, bond wires 112 are coupled to pads 106 and 110 using contacting structures 108 and 111, such as solder balls or bumps. As shown, contacting structures 108 are coupled to pads 106, and contacting structures 111 are coupled to pads 110.

In some embodiments, bond wires 112 serve as connection mechanism between semiconductor devices 102 and substrate 104. In some examples, bond wires 112 can establish necessary electrical connection between semiconductor devices 102 and substrate 104. Bond wires 112 can provide power connections and enable signal transmission, such as data, clock, and control signals, between semiconductor devices 102 and substrate 104.

In some examples, a bond wire 112 can include a conductive material such as gold, aluminum, copper, or silver. In some examples, contacting structures 108 can be solder balls or bumps. In some examples, a contacting structure 108 or 111 can include a solder material, such as lead-tin (Pb—Sn) alloy or tin-silver-copper (Sn—Ag—Cu). In some examples, a contacting structure 108 or 111 can include eutectic or near-eutectic compositions to ensure a sharp melting point and improved performance.

Package structure 100 further includes contacting structures 116 to bond substrate 104 to an adjacent semiconductor device 102. In the shown example, contacting structures 116 are used to couple the adjacent semiconductor device 102 to substrate 104 using flip-chip bonding. In some embodiments, contacting structures 116 are similar to contacting structures 108 and 111. Accordingly, some descriptions of contacting structures 116 are omitted here for brevity.

Package structure 100 further includes contacting structures 118 attached to the bottom side of substrate 104. In some embodiments, contacting structures 118 are configured to enable connection from package structure 100 to external components or systems, such as a printed circuit board (PCB). In some embodiments, contacting structures 118 are similar to contacting structures 108 and 111. Accordingly, some descriptions of contacting structures 118 are omitted here for brevity.

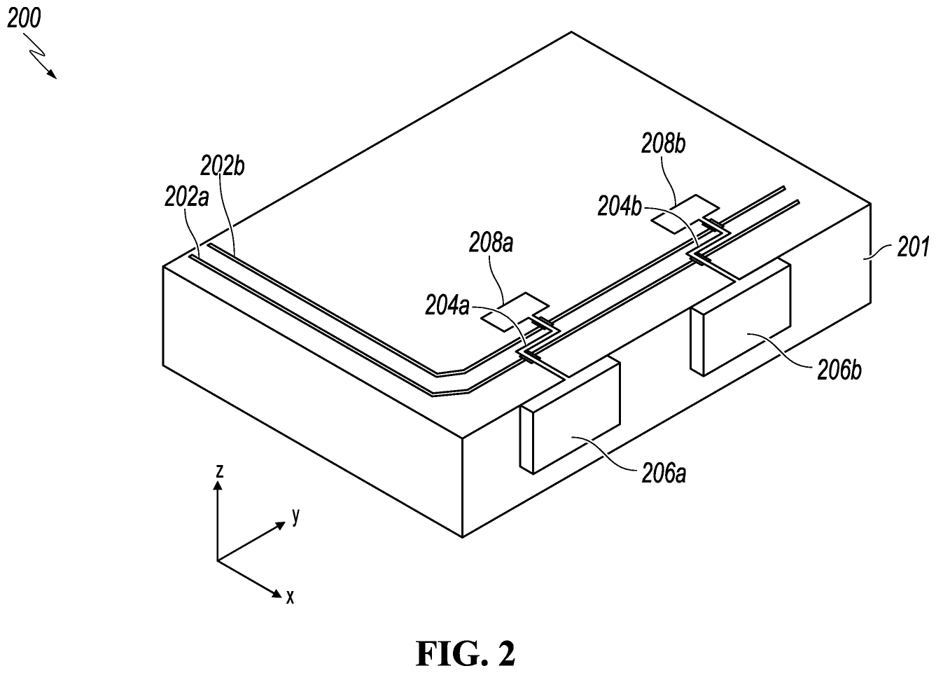

In some embodiments, semiconductor devices 102 are aligned along one side of semiconductor devices 102. In the shown example, semiconductor devices 102 are aligned along a side of semiconductor devices 102 on which pads 106 are located, and the side on which pads 106 are located has a surface parallel to the stacking direction, e.g., z-axis. In some embodiments, the side of semiconductor devices 102 on which pads 106 are located can have various configurations, which will be discussed below with reference to FIGS. 2-6 in greater detail. By aligning the semiconductor devices on one side and bonding them on the aligned side, a stacking area of the semiconductor devices can be reduced, thereby increasing stacking density and improving performance.

FIG. 2 shows a schematic diagram of an example semiconductor device 200, in accordance with some embodiments of the present disclosure. In some embodiments, semiconductor device 200 is an example of one or more of semiconductor devices 102 in FIG. 1. In some embodiments, semiconductor device 200 is similar to a semiconductor device 102. Accordingly, some descriptions of semiconductor device 200 are omitted here for brevity.

As shown, semiconductor device 200 includes sealing structures 202a and 202b. Note that semiconductor device 200 is shown to include two sealing structures for illustratively purpose only. In some examples, semiconductor device 200 can have any suitable number of sealing structures, such as 1, 3, or 4.

In some embodiments, sealing structures 202a and 202b are configured to provide a boundary between the semiconductor device 200's active devices and the device 200's edge, acting as moisture barriers, electrical shields, and stress relief structures. In some examples, sealing structures 202a and 22b can be configured to protect the sensitive internal elements, such as a circuitry, from potential contaminants or particles during the die manufacturing process, and act as a barrier against impurities that might inadvertently be introduced during a wafer dicing process. In some examples, sealing structures 202a and 202b can be configured to provide a stable mechanical structure that can absorb some of the stress and strain during packaging, reducing the chance of fractures or damage to the device 200's interior. In some examples, sealing structures 202a and 202b can be configured to provide electrical isolation, ensuring that potential crosstalk or interference between the device 200's internal and external elements is minimized. In some examples, sealing structures 202a and 202b can be configured to help in controlling or preventing unintended leakage currents from traveling around the device 200's perimeter. In some examples, sealing structures 202a and 202b can be configured to serve as a well-defined area for testing purposes.

In some embodiments, sealing structures 202a and 202b include one or more of following materials: polysilicon, silicon nitride (Si₃N₄), silicon oxynitride (SiON), silicon dioxide (SiO₂), metals, low-k dielectrics, etc. In some examples, the composition and layering of materials in sealing structures 202a and 202b can depend on the specific die manufacturing technology, the requirements of the application, and the potential challenges (like moisture, contaminants, or electrical interference) that the device 200 might encounter in its intended environment.

In some embodiments, sealing structures 202a and 202b extends vertically, e.g., along the z-axis, into semiconductor device 200. In some examples, the vertical depth of sealing structures 202a and 202b can range from a few micrometers to several tens of micrometers, depending on the technology node (e.g., 5 nm, 10 nm, or 28 nm), the die's intended application, and the die design's particular requirement.

Semiconductor device 200 further includes wires 204a and 204b. In some embodiments, wires 204a and 204b are configured such that they are routed through sealing structures 202a and 202b, but they are isolated from sealing structures 202a and 202b. In the shown example, wires 204a and 204b are configured to have a z-shape route through sealing structures 202a and 202b. In some examples, wires 204a and 204b can have any suitable configuration of route through sealing structures 202a and 202b. In some examples, wires 204a and 204b can include a conductive material, such as gold, aluminum, copper, or silver, depending on the application and the required properties.

In the shown example, one ends of wires 204a and 204b are coupled to pads 206a and 206b, respectively. As shown, pads 206a and 206b are located on a side surface 201 of semiconductor device 200 that is parallel to the z-axis. In some embodiments, pads 206a and 206b are similar to pads 106. Accordingly, some descriptions of pads 206a and 206b are omitted here for brevity. In the shown example, pads 206a and 206b have a rectangular structure. In some examples, pads 206a and 206b can have any suitable type of structure, such as square, oval, trapezoid, or rhombus.

In the shown example, the other ends of wires 204a and 204b are coupled to contacting structures 208a and 208b. In some embodiments, contacting structures 208a and 208b are configured to provide connections to internal elements or circuitry (not shown) of semiconductor device 200. In some examples, contacting structures 208a and 208b can include a conductive material such as aluminum, copper, or tungsten.

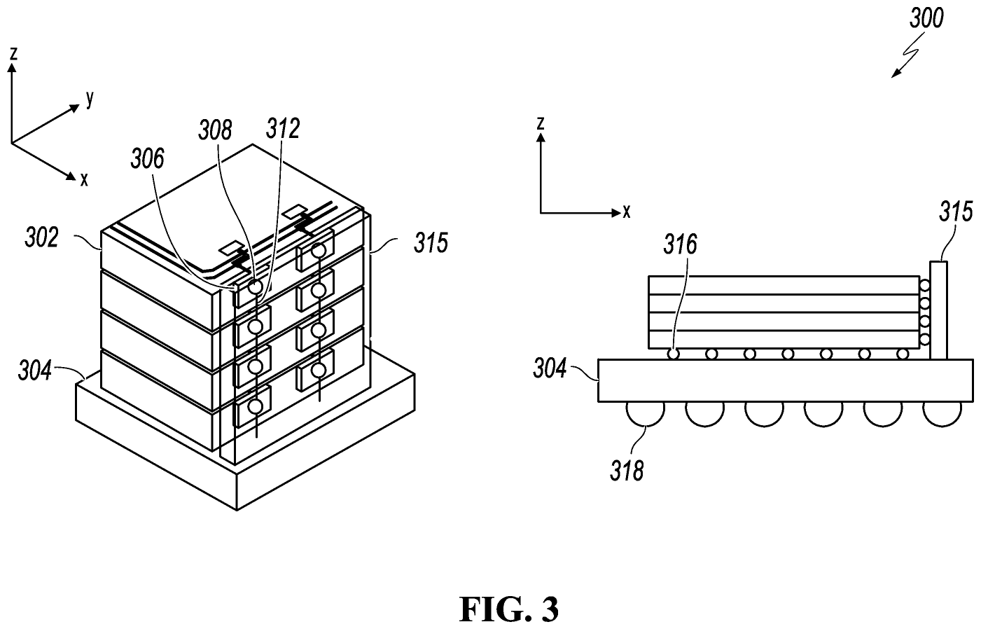

FIG. 3 shows a schematic diagram of an example package structure 300, according to some embodiments of the present disclosure. As shown, package structure 300 includes multiple semiconductor devices 302 stacked over substrate 304. In some embodiments, some elements of package structure 300 are similar or analogous to some elements of package 100. For example, semiconductor devices 302 are similar to semiconductor devices 102, and substrate 304 is similar to substrate 104. Accordingly, some descriptions of these similar or analogous elements are omitted here for brevity.

In the shown example, package structure 300 includes coupling structure 315. In some embodiments, coupling structure 315 is configured to interconnect semiconductor devices 302 and substrate 304 horizontally, allowing for high-density, high performance multi-die configuration. In some embodiments, coupling structure 315 serves as an intermediate layer that provides electrical routing between semiconductor devices 302 and substrate 304, allowing for more complex and denser connections between semiconductor devices 302 and substrate 304. In some examples, coupling structure 315 is an interposer.

In the shown example, coupling structure 315 includes contacting structures 308 coupled to pads 306 of semiconductor devices 302. In some embodiments, coupling structure 315 further includes an internal circuit layer 312 configured to interconnect contacting structures 308. In the shown example, internal circuit layer 312 include wires interconnecting contacting structures 308. In some examples, the wires can include one or more conductive materials of gold, aluminum, copper, or silver, etc.

In some examples, coupling structure 315 can include a material such as single crystal of silicon, silicon-on-insulator (SOI), or compound semiconductor. In some examples, a contacting structure 308 can include a solder material such as lead-tin (Pb—Sn) alloy or tin-silver-copper (Sn—Ag—Cu) alloy. In some examples, a contacting structure 308 can include a eutectic or near-eutectic composition to ensure a sharp melting point and improved performance. In an example process of bonding coupling structure 315 to semiconductor devices 302 and substrate 304, contacting structures 308 can be melted and bonded to respective pads 306.

In some embodiments, contacting structures 316 and 318 are similar to contacting structures 116 and 118. Accordingly, some descriptions of contacting structures 316 and 318 are omitted here for brevity.

Note that, in the shown example of FIG. 3, semiconductor devices 302 are aligned on a side surface where pads 306 are located. Coupling structure 315 is parallel to the stacking direction, e.g., the z direction, and is used to interconnect pads 306, therefore, bonding semiconductor devices 302. By aligning semiconductor devices 302 on one side and using coupling structure 315 to bond semiconductor devices 302 on the aligned side, a stacking area of semiconductor devices 302 can be reduced, thereby increasing stacking density and improving performance.

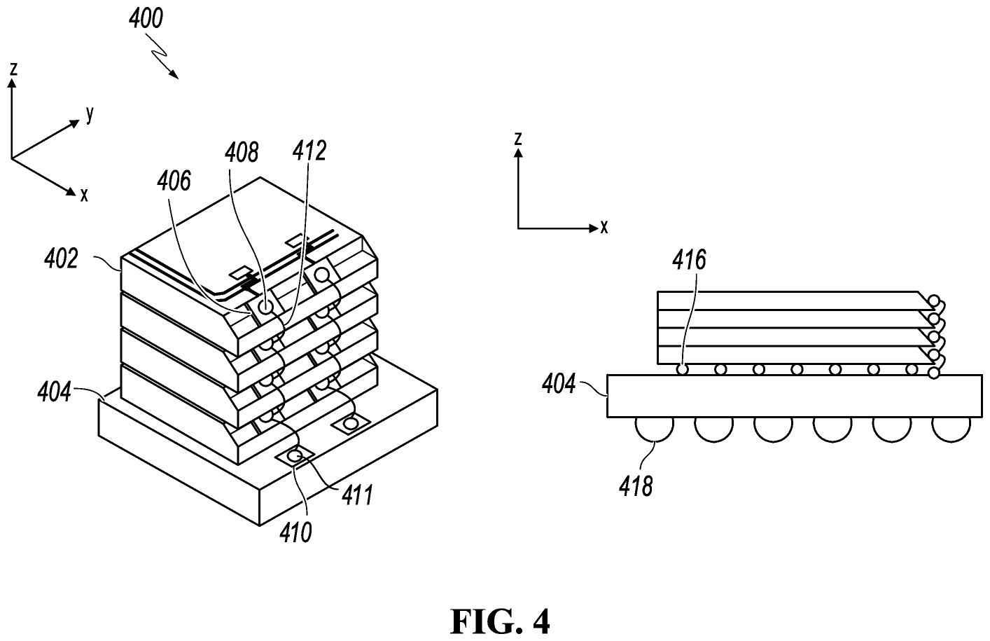

FIG. 4 shows a schematic diagram of an example package structure 400, according to some embodiments of the present disclosure. In some embodiments, some elements of package structure 400 are similar or analogous to some elements of package 100. For example, semiconductor devices 402 are similar to semiconductor devices 102, and substrate 404 is similar to substrate 104. Accordingly, some descriptions of these similar or analogous elements are omitted here for brevity.

In some embodiments, semiconductor devices 402 are aligned along one side of semiconductor devices 402. In the shown example, semiconductor devices 402 are aligned along a side of semiconductor devices 402 where pads 406 are located. Each semiconductor device 402 includes an inclined side surface on the aligned side, and the inclined side surface has an acute angle θ, e.g., 0<θ<90°, with respect to the stacking direction, e.g., z-axis. Pads 406 are located on the inclined side surfaces. In some examples, the inclined side surfaces of semiconductor devices 402 can have varied acute angles.

By aligning the semiconductor devices 402 on one side and bonding them on the aligned side, a stacking area of semiconductor devices 402 can be reduced, thereby increasing stacking density and improving performance.

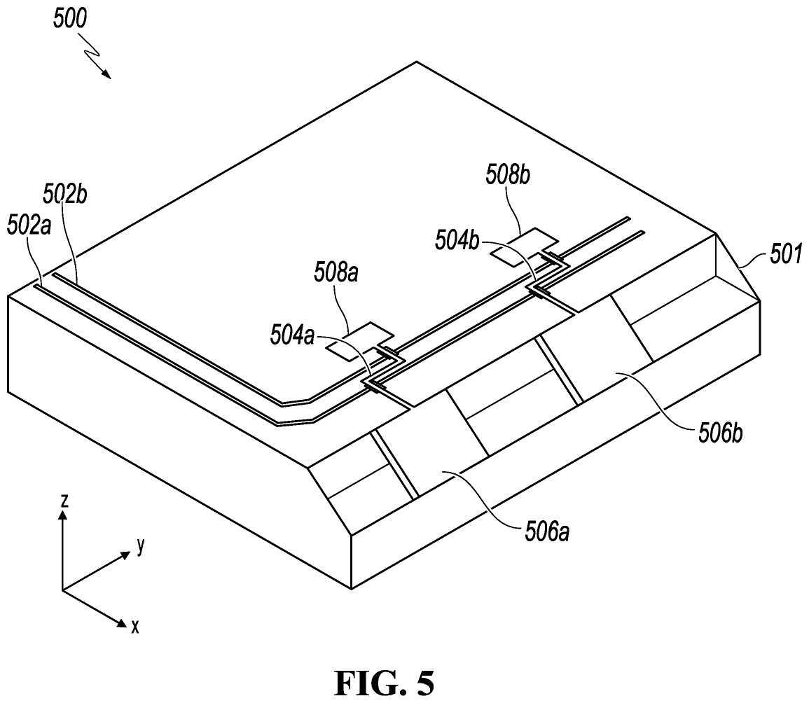

FIG. 5 shows a schematic diagram of an example semiconductor device 500, according to some embodiments of the present disclosure. In some embodiments, semiconductor device 500 is an example of one or more of semiconductor devices 402 in FIG. 4. In some embodiments, some elements in FIG. 5 are similar or analogous to some elements in FIG. 2. For example, sealing structures 502a and 502b are similar to sealing structures 202a and 202b, wires 504a and 504b are similar to wires 204a and 204b, pads 506a and 506b are similar to pads 206a and 206b, and contacting structures 508a and 508b are similar to contacting structures 208a and 208b. Accordingly, some descriptions of these similar or analogous elements are omitted here for brevity.

In some embodiments, sealing structures 502a and 502b are configured to provide a boundary between the semiconductor device 500's active devices and the device 500's edge, acting as moisture barriers, electrical shields, and stress relief structures.

In some embodiments, wires 504a and 504b are configured such that they are routed through sealing structures 502a and 502b, but they are isolated from sealing structures 502a and 502b. In the shown example, wires 504a and 504b are configured to have a z-shape route through sealing structures 502a and 502b. In some examples, wires 504a and 504b can have any suitable configuration of route through sealing structures 502a and 502b.

In the shown example, one ends of wires 504a and 504b are coupled to pads 506a and 506b, respectively. The other ends of wires 504a and 504b are coupled to contacting structures 508a and 508b. As shown, pads 506a and 506b are located on an inclined side surface 501 of semiconductor device 500 that has an acute angle with respect to the z-axis.

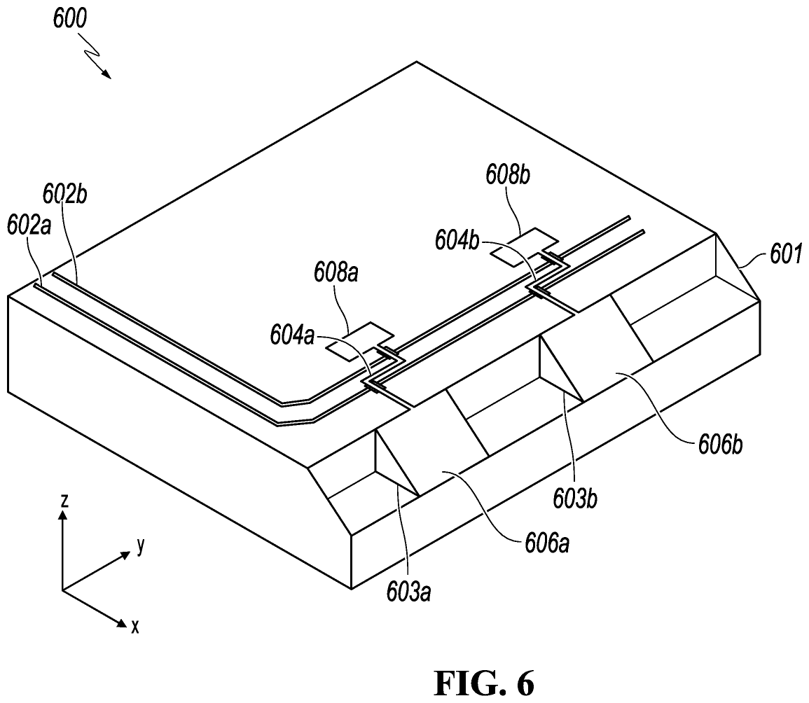

FIG. 6 shows a schematic diagram of an example semiconductor device 600, according to some embodiments of the present disclosure. In some embodiments, semiconductor device 600 is an example of one or more of semiconductor devices 402 in FIG. 4. In some embodiments, some elements in FIG. 5 are similar or analogous to some elements in FIG. 2. For example, sealing structures 602a and 602b are similar to sealing structures 202a and 202b, wires 604a and 604b are similar to wires 204a and 204b, pads 606a and 606b are similar to pads 206a and 206b, and contacting structures 608a and 608b are similar to contacting structures 208a and 208b. Accordingly, some descriptions of these similar or analogous elements are omitted here for brevity.

In some embodiments, sealing structures 602a and 602b are configured to provide a boundary between the semiconductor device 600's active devices and the device 600's edge, acting as moisture barriers, electrical shields, and stress relief structures.

In some embodiments, wires 604a and 604b are configured such that they are routed through sealing structures 602a and 602b, but they are isolated from sealing structures 602a and 602b. In the shown example, wires 604a and 604b are configured to have a z-shape route through sealing structures 602a and 602b. In some examples, wires 604a and 604b can have any suitable configuration of route through sealing structures 602a and 602b.

In the shown example, one ends of wires 604a and 604b are coupled to pads 606a and 606b, respectively. The other ends of wires 604a and 604b are coupled to contacting structures 608a and 608b. As shown, semiconductor device 600 includes an inclined side surface 610, and recessed structures 603a and 603b are located at inclined side surface 601. Pads 606a and 606b are disposed in recessed structures 603a and 603b, respectively. In the shown example, pads 606a and 606b have a polyhedron structure with two triangular side surfaces. In some examples, pads 606a and 606b can have any suitable sizes and shapes that fit recessed structures 603a and 603b.

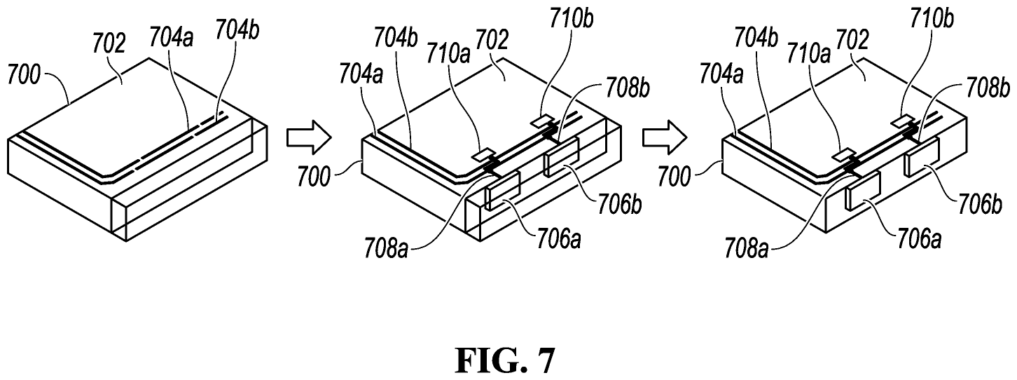

FIG. 7 shows an example process of manufacturing a semiconductor device, according to some embodiments of the present disclosure. In some examples, the process described herein can be used to manufacture any suitable semiconductor devices, such as semiconductor devices 102, 200, 302, 402, 500, or 600. As shown, the example process starts with providing semiconductor layer 700. In some examples, semiconductor layer 700 can be manufactured using one or more processes of wafer preparation, oxidation, photolithography, etching, doping, chemical vapor deposition (CVD), metallization, planarization, layering, dicing, packaging, etc.

In some embodiments, semiconductor layer 700 includes a functional circuit. In some examples, semiconductor layer 700 can be manufactured by depositing multiple layers of various materials and etching them onto a semiconductor wafer in intricate patterns defined by a chip design. After the wafer fabrication process is complete, the wafer that includes individual circuits is cut and diced into individual pieces, each of which is a die. Each die includes a fully functional electronic circuit, which can be a microprocessor, memory, sensor, or any other suitable type of integrated circuit. In some embodiments, each die is encapsulated in a protective package, providing physical support, protection from environmental factor, and connections (e.g., through pins or solder balls) to external devices or system.

In the shown examples, semiconductor layer 700 includes sealing structures 704a and 704b. In some embodiments, sealing structures 704a and 704b are manufactured by masking a surface, such as surface 702 of semiconductor layer 700, and etching unprotected area on the masked surface. For example, to define the shape and location of the sealing structures 704a and 704b, a layer of photoresist material is deposited on surface 702 of semiconductor layer 700. Semiconductor layer 700 is then exposed to ultraviolet (UV) light through a mask that blocks the light in the shape of the desired patterns (including sealing structures 704a and 704b). The exposed regions can undergo chemical changes, allowing them to be etched away, leaving behind the desired patterns. In some examples, wet or dry etching techniques can be used to etch away the unprotected areas (those areas not covered by the photoresist material) to further define sealing structure 704a and 704b.

In some embodiments, some spaces at surface 702 are reserved to route wires, such as wires 708a and 708b, through sealing structure 704a and 704b. In some embodiments, an example process of manufacturing wires 708a and 708b includes dielectric deposition, trench patterning, etching, barrier layer deposition, metal deposition, chemical mechanical planarization (CMP), etc. For example, a dielectric layer can be deposited on surface 702 of semiconductor layer 700. The dielectric layer can electrically isolate the wires from other components and from each other. The dielectric layer can include silicon dioxide (SiO2) or low-k dielectrics, which reduce capacitive crosstalk between adjacent metal lines. Then, photolithography can be used to form patterns for trenches (which will house the horizontal wires) that are defined on the dielectric layer. In some examples, a layer of photoresist material can be applied on the dielectric layer, exposed through a mask with the desired pattern, and developed to leave behind a patterned protective layer. The unprotected areas of the dielectric can be etched away using plasma (dry) etching, creating trenches. In some examples, before depositing the metal for the wires, a thin barrier layer is deposited. This can prevent metal diffusion into the dielectric. The barrier layer can include a material such as titanium, titanium nitride, tantalum, or tantalum nitride. Wires 708a and 708b can be formed by depositing a metallic material, such as copper, into the trenches using an electroplating process. After metal deposition, CMP can be used to polish away excess metal and dielectric, leaving a flat surface with metal only in the trenches.

In some embodiments, wires 708a and 708b and pads 706a and 706b are manufactured simultaneously or within a same time period and using a similar manufacturing process. According, the manufacturing process of pads 706a and 706b are omitted here for brevity.

After wires 708a and 708b and pads 706a and 706b are formed, a portion of semiconductor layer 700 is removed to expose pads 706a and 706b.

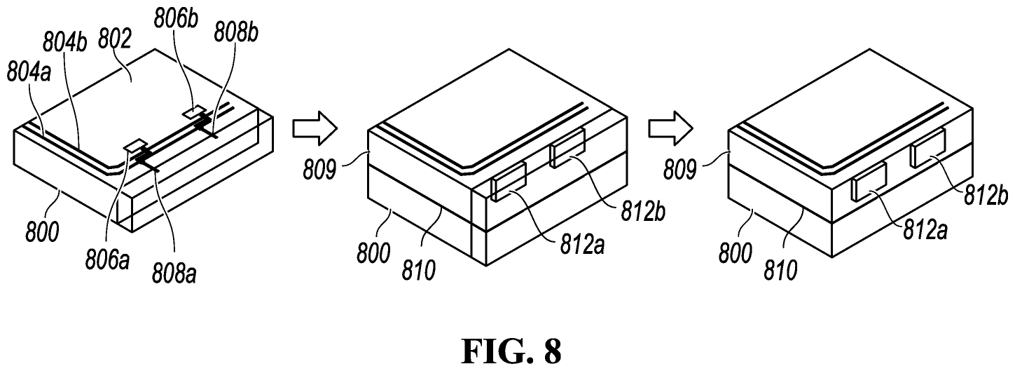

FIG. 8 shows another example process of manufacturing a semiconductor device, according to some embodiments of the present disclosure. In some examples, the process described herein can be used to manufacture any suitable semiconductor devices, such as semiconductor devices 102, 200, 302, 402, 500, or 600. The example process can start with forming wires 808a and 808b on surface 802 of first semiconductor layer 800. In the shown example, wires 808a and 808b are configured to route through sealing structures 804a and 804b, but they are isolated from sealing structures 804a and 804b.

In some embodiments, an example process of manufacturing wires 808a and 808b includes dielectric deposition, trench patterning, etching, barrier layer deposition, metal deposition, chemical mechanical planarization (CMP), etc. For example, a dielectric layer can be deposited on surface 802 of first semiconductor layer 800. The dielectric layer can electrically isolate the wires from other components and from each other. The dielectric layer can include silicon dioxide (SiO2) or low-k dielectrics, which reduce capacitive crosstalk between adjacent metal lines. Then, photolithography can be used to form patterns for trenches (which will house the wires) that are defined on the dielectric layer. In some examples, a layer of photoresist material can be applied on the dielectric layer, exposed through a mask with the desired pattern, and developed to leave behind a patterned protective layer. The unprotected areas of the dielectric can be etched away using plasma (dry) etching, creating trenches. In some examples, before depositing the metal for the wires, a thin barrier layer is deposited. This can prevent metal diffusion into the dielectric. The barrier layer can include material such as titanium, titanium nitride, tantalum, or tantalum nitride. Wires 808a and 808b can be formed by depositing a metallic material, e.g., copper, into the trenches using an electroplating process. After metal deposition, CMP can be used to polish away excess metal and dielectric, leaving a flat surface with metal only in the trenches.

After forming wires 808a and 808b on surface 802, second semiconductor layer 809 is deposited on surface 802 of first semiconductor layer 800 to form stacked semiconductor layer 810. In some embodiments, second semiconductor layer 809 and first semiconductor layer 800 include a same material.

Pads 812a and 812b are then formed in stacked semiconductor layer 810. In some embodiments, pads 812a and 812b can be formed by using a similar process of manufacturing pads 706a and 706b. Accordingly, the manufacturing process of pads 812a and 812b are omitted here for brevity. In some embodiments, such as the shown example of FIG. 8, after second semiconductor layer 809 is deposited on first semiconductor layer 800, wires 808a and 808b are concealed (“invisible”) in stacked layer 810. As shown, one ends of wires 808a and 808b are coupled to contacting structures 806a and 806b, respectively. The other ends of wires 808a and 808b are coupled to pads 812a and 812b, respectively.

In some embodiments, pads 812a and 812b are formed close to an edge of stacked layer 810. Then, a portion of stacked layer 810 that is close to the edge is removed to expose pads 812a and 812b.

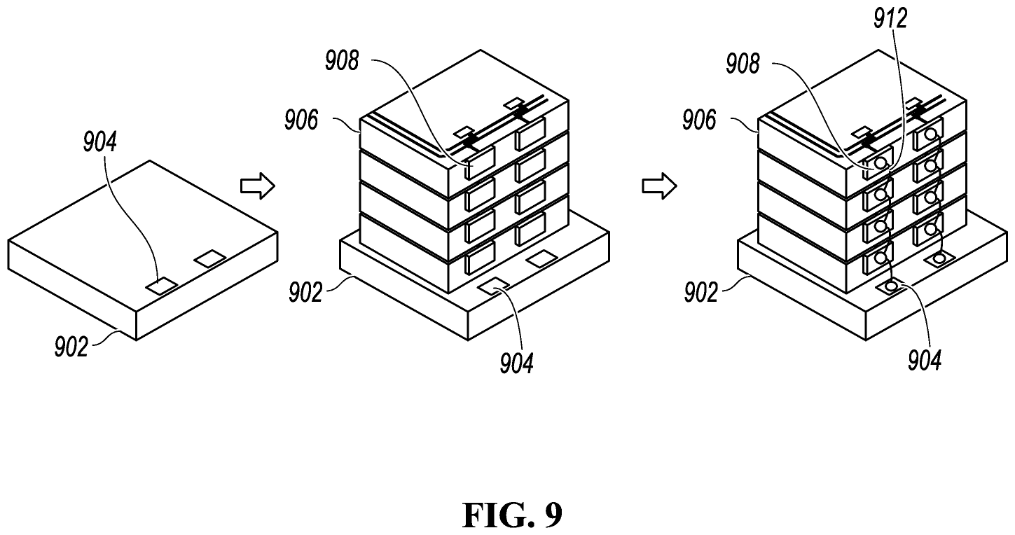

FIG. 9 shows an example process of manufacturing a package structure, according to some embodiments of the present disclosure. In some examples, the process described herein can be used to manufacture any suitable package structures, such as package structures 100 or 400.

The process can start with providing substrate 902 that includes pads 904. Then, semiconductor devices 906 are stacked over substrate 902. Each semiconductor device 906 includes two pads 908. A first semiconductor device 906 (or the bottom semiconductor device 906 adjacent to substrate 902) can be attached to substrate 902 using a die attach material, which can be adhesive, epoxy, or solder. A second semiconductor device 906 can then be aligned and attached to first semiconductor device 906. This process can be repeated until all semiconductor devices 906 are attached. Then, wires 912, such as copper or gold wires, can be used to bond pads 904 on one semiconductor device 906 to pads 904 on an adjacent semiconductor device 906.

In some examples, such as the example shown in FIG. 9, a ball bonding process can be used to bond pads 904 using wires 912. In an example balling bonding process, a solder ball can be created at a wire 912's end (e.g., by melting it with an electric flame-off), then pressed onto a pad 904 to form a bond.

In some examples, a wedge bonding process can be used to bond pads 904 using wires 912. In an example wedge bonding process, a wire 912 is directly coupled to a pad 904 using a wedge-shaped tool.

In some embodiments, a process of bonding a pad 904 of substrate 902 to a pad 908 of an adjacent semiconductor device 906 is similar to the process of bonding pads 904 of two adjacent semiconductor devices 906. Accordingly, the process of bonding a pad 904 to a pad 908 is omitted here for brevity.

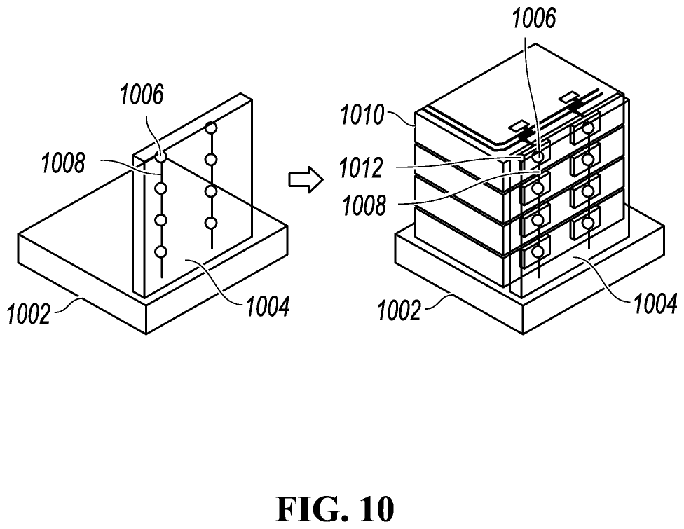

FIG. 10 shows another example process of manufacturing a package structure, according to some embodiments of the present disclosure. In some examples, the process described herein can be used to manufacture any suitable package structures, such as package structure 300.

The process can start with bonding coupling structure 1004 to substrate 1002. In the shown examples, coupling structure 1004 includes contacting structures 1006. In some examples, a contacting structure 1006 can be a solder ball or a solder bump. In some embodiments, one or more contacting structures 1006 of coupling structure 1004 are coupled to one or more pads (not shown) of substrate 1002. In the shown example, contacting structures 1006 are arranged in two columns. In some examples, contacting structures 1006 can be arranged in any suitable number of columns or in any suitable arrangements. In some embodiments, coupling structure 1004 includes an internal circuit layer. In the shown example, the internal circuit layer includes wires 1008, such as gold or copper wires, interconnecting contacting structures 1006.

After bonding coupling structure 1004 to substrate 1002, semiconductor devices 1010 are stacked over substrate 1002. Each semiconductor device 1010 includes two pads 1012 in FIG. 10. In some examples, each semiconductor device 1010 can have any suitable number of pads 1012.

A first semiconductor device 1010 (or the bottom semiconductor device 1010 adjacent to substrate 1002) is attached to substrate 1002 using a die attach material, which can be adhesive, epoxy, or solder. A second semiconductor device 1010 can then be aligned and attached to first semiconductor device 1010. This process can be repeated until all semiconductor devices 1010 are attached.

Coupling structure 1004 can be used to bond pads 1012 of one semiconductor device 1010 to pads 1012 of an adjacent semiconductor device 1010. In the shown example, contacting structures 1006 of coupling structure 1004 are aligned to and in contact with respective pads 1012 of semiconductor devices 1010. In some examples, when contacting structures 1006 are solder balls or solder bumps, the solder balls or solder bumps can be melted to be bonded to respective pads 1012.

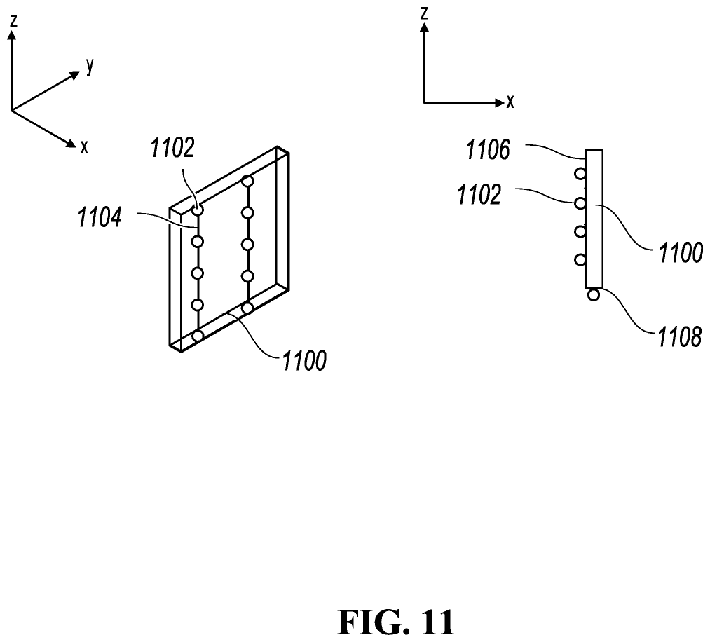

FIG. 11 shows a schematic diagram of an example coupling structure 1100, according to some embodiments of the present disclosure. In some embodiments, coupling structure 1100 is an example of one or more of coupling structures 315 and 1004. In some examples, coupling structure 1100 can include a material such as single crystal of silicon, silicon-on-insulator (SOI), or compound semiconductor.

In the shown example, coupling structure 1100 includes contacting structures 1102. In some examples, contacting structures 1102 can be solder balls or solder bumps. In some examples, a contacting structure 1102 can include a solder material such as lead-tin (Pb—Sn) alloy or tin-silver-copper (Sn—Ag—Cu) alloy. In some examples, a contacting structure 1102 can include a eutectic or near-eutectic composition to ensure a sharp melting point and improved performance.

Coupling structure 1100 further includes an internal circuit layer 1104. In some examples, internal circuit layer 1104 can include wires interconnecting contacting structures 1102, and the wires can include one or more conductive materials of gold, aluminum, copper, or silver, etc.

In the shown example, coupling structure 1100 includes surface 1106 and surface 1108. One or more contacting structures 1102 are disposed on surface 1106, and one or more contacting structures 1102 are disposed on surface 1108. In some examples, surface 1106 and surface 1108 are perpendicular to each other. In some examples, one or more contacting structures 1102 on surface 1106 can be bonded to pads of one or more semiconductor devices, such as semiconductor devices 102, 200, 302, 1010. One or more contacting structures 1102 on surface 1108 can be bonded to pads of a substrate, such as substrates 104, 304, 1002.

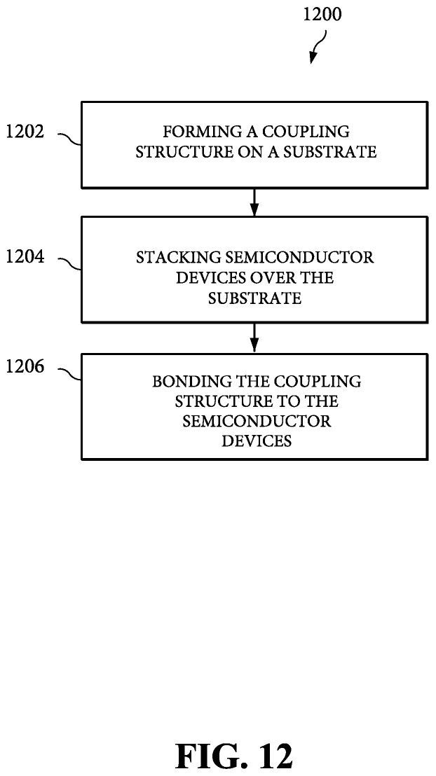

FIG. 12 shows a flowchart of an example process 1200 of manufacturing a package structure, in accordance with some embodiments of the present disclosure. In some implementations, some or all of the operations in process 1200 are implemented based on the techniques described in connection with FIGS. 1-11. The operations shown in process 1200 may not be exhaustive and that other operations can be performed as well before, after, or in between any of the illustrated operations. Further, some of the operations may be performed simultaneously, or in a different order than shown in FIG. 12.

Process 1200 starts with forming a coupling structure over a substrate (1202). In some embodiments, the coupling structure, e.g., coupling structure 1004, is perpendicular to the substrate, e.g., substrate 1002.

In some embodiments, the coupling structure includes first contacting structures, e.g., contacting structures 1102, on a first side surface, e.g., surface 1106, of the coupling structure and second contacting structures on a second side surface, e.g., surface 1108, of the coupling structure. In some examples, the first side surface of the coupling structures is perpendicular to the second side surface of the coupling structure. In some examples, the second side surface of the coupling structure can be in parallel with the substrate, and one or more contacting structures on the second side surface can be bonded to one or more pads of the substrate.

Semiconductor devices are stacked over the substrate (1204). In some embodiments, one or more pads, e.g., pads 1012, are formed on a side surface of one or more of the semiconductor devices, e.g., devices 1010.

In some examples, forming the one or more pads on the side surface of one or more semiconductor devices includes forming a semiconductor layer (e.g., semiconductor layer 700), forming one or more wires (e.g., wires 708a and 708b) and one or more pads (e.g., pads 706a and 706b) on the semiconductor layer, and removing a portion of the semiconductor layer to expose the one or more pads. In some examples, the wires and pads can be manufactured simultaneously or within a same time period.

In some examples, forming the one or more pads on the side surface of one or more semiconductor devices including forming one or more wires (e.g., wires 808a and 808b) at a surface of a first semiconductor structure (e.g., semiconductor layer 800). The one or more wires can be routed through from one or more sealing structures (e.g., sealing structures 804a and 804b) of the first semiconductor layer, but the wires are isolated from the sealing structures. A second semiconductor layer (e.g., semiconductor layer 809) can be deposited on the surface of the first semiconductor layer to form a stacked layer (e.g., semiconductor layer 810). In some examples, the first semiconductor layer and the second semiconductor layer can include a same semiconductor material. A portion of the stacked layer can then be removed to expose the one or more pads.

Process 1200 further includes bonding the coupling structure to the semiconductor devices (1206). In some embodiments, bonding the coupling structure to the semiconductor devices includes bonding one or more of the first contacting structures of the coupling structure to one or more pads of the semiconductor devices.

Although specific configurations and arrangements are discussed, it should be understood that this is done for illustrative purposes only. A person of ordinary skill in the pertinent art will recognize that other configurations and arrangements can be used without departing from the spirit and scope of the present disclosure. It will be apparent to a person of ordinary skill in the pertinent art that the present disclosure can also be employed in a variety of other applications.

References in the specification to “one embodiment,” “an embodiment,” “an example embodiment,” “some embodiments,” etc., indicate that the embodiment described may include a particular feature, structure, or characteristic, but other embodiments may not necessarily include the particular feature, structure, or characteristic. Moreover, such phrases do not necessarily refer to the same embodiment. Further, when a particular feature, structure, or characteristic is described in connection with an embodiment, it would be within the knowledge of a person of ordinary skill in the pertinent art to effect such feature, structure or characteristic in connection with other embodiments whether or not explicitly described.

In general, terminology may be understood at least in part from usage in context. For example, the term “one or more” as used herein, depending at least in part upon context, may be used to describe any feature, structure, or characteristic in a singular sense or may be used to describe combinations of features, structures or characteristics in a plural sense. Similarly, terms, such as “a,” “an,” or “the,” again, may be understood to convey a singular usage or to convey a plural usage, depending at least in part upon context. In addition, the term “based on” may be understood as not necessarily intended to convey an exclusive set of factors and may, instead, allow for existence of additional factors not necessarily expressly described, again, depending at least in part on context.

It should be readily understood that the meaning of “on,” “above,” and “over” in the present disclosure should be interpreted in the broadest manner such that “on” not only means “directly on” something but also includes the meaning of “on” something with an intermediate feature or a layer therebetween, and that “above” or “over” not only conveys the meaning of “above” or “over” something but can also include the meaning it is “above” or “over” something with no intermediate feature or layer therebetween (i.e., directly on something).

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, the term “substrate” refers to a material onto which subsequent material layers are added. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically non-conductive material, such as a glass, a plastic, or a sapphire wafer.

As used herein, the term “layer” refers to a material portion including a region with a thickness. A layer can extend over the entirety of an underlying or overlying structure or may have an extent less than the extent of an underlying or overlying structure. Further, a layer can be a region of a homogeneous or inhomogeneous continuous structure that has a thickness less than the thickness of the continuous structure. For example, a layer can be located between any pair of horizontal planes between, or at, a top surface and a bottom surface of the continuous structure. A layer can extend horizontally, vertically, and/or along a tapered surface. A substrate can be a layer, can include one or more layers therein, and/or can have one or more layers thereupon, thereabove, and/or therebelow. A layer can include multiple layers. For example, an interconnect layer can include one or more conductor and contact layers (in which interconnect lines and/or vertical interconnect access (via) contacts are formed) and one or more dielectric layers.

As used herein, the term “about” indicates the value of a given quantity that can vary based on a particular technology node associated with the subject semiconductor device. Based on the particular technology node, the term “about” can indicate a value of a given quantity that varies within the value.

It is to be noted that although process steps, method steps, algorithms or the like may be described in a sequential order above, such processes, methods and algorithms may generally be configured to work in alternate orders, unless specifically stated to the contrary.

While this document may describe many specifics, these should not be construed as limitations on the scope of an invention that is claimed or of what may be claimed, but rather as descriptions of features specific to particular embodiments. Certain features that are described in this document in the context of separate embodiments can also be implemented in combination in a single embodiment. Conversely, various features that are described in the context of a single embodiment can also be implemented in multiple embodiments separately or in any suitable sub-combination. Moreover, although features may be described above as acting in certain combinations and even initially claimed as such, one or more features from a claimed combination in some cases can be excised from the combination, and the claimed combination may be directed to a sub-combination or a variation of a sub-combination. Similarly, while operations are depicted in the drawings in a particular order, this should not be understood as requiring that such operations be performed in the particular order shown or in sequential order, or that all illustrated operations be performed, to achieve desirable results.

Only a few examples and implementations are disclosed. Variations, modifications, and enhancements to the described examples and implementations and other implementations can be made based on what is disclosed.

What is claimed is:

1. A package structure, comprising a substrate and semiconductor devices stacked over the substrate, wherein the semiconductor devices are stacked along a first direction, and at least one of the semiconductor devices comprises one or more pads located on a side surface of the at least one of the semiconductor devices.

2. The package structure of claim 1, wherein the semiconductor devices are aligned along one side of the semiconductor devices.

3. The package structure of claim 1, wherein at least one of the semiconductor devices comprises a side surface parallel to the first direction, and one or more pads of the at least one of the semiconductor devices are disposed on the side surface.

4. The package structure of claim 1, wherein at least one of the semiconductor devices comprises a side surface having an acute angle with the first direction, and one or more pads of the at least one of the semiconductor devices are disposed on the side surface.

5. The package structure of claim 1, wherein at least one of the semiconductor devices comprises a side surface having an acute angle with the first direction, and one or more pads of the at least one of the semiconductor devices are disposed in a recessed structure at the side surface.

6. The package structure of claim 1, wherein the substrate comprises one or more pads, and the package structure further comprises bond wires coupling pads of the semiconductor devices and the substrate.

7. The package structure of claim 1, wherein the package structure further comprises one or more contacting structures on the substrate, wherein the one or more contacting structures are coupled to a neighboring semiconductor device.

8. The package structure of claim 1, wherein the package structure further comprises a coupling structure parallel to the first direction, and the coupling structure is configured to couple the semiconductor devices and the substrate.

9. The package structure of claim 8, wherein the coupling structure comprises contacting structures coupled to pads of the semiconductor devices and the substrate.

10. The package structure of claim 1, wherein at least one of the semiconductor devices comprises one or more sealing structures.

11. The package structure of claim 10, wherein the at least one of the semiconductor devices further comprises one or more wires routed through and isolated from the one or more sealing structures.

12. The package structure of claim 11, wherein the one or more wires are coupled to one or more pads of the at least one of the semiconductor devices.

13. A coupling structure, comprising:
first contacting structures on a first side surface of the coupling structure; and
second contacting structures on a second side surface of the coupling structure, wherein the second side surface is perpendicular to the first side surface.

14. The coupling structure of claim 13, wherein the first contacting structures are coupled to semiconductor devices, and the second contacting structures are coupled to a substrate.

15. The coupling structure of claim 13, wherein the coupling structure comprises a circuit layer coupled to the first contacting structures and the second contacting structures.

16. A method for manufacturing a package structure, the method comprising:
forming a coupling structure on a substrate, wherein the coupling structure is perpendicular and coupled to the substrate, the coupling structure comprises first contacting structures on a first side surface of the coupling structures and second contacting structures on a second side surface of the coupling structure, and the second side surface is perpendicular to the first side surface;
stacking semiconductor devices over the substrate; and
bonding the coupling structure to the semiconductor devices.

17. The method of claim 16, further comprising:
forming one or more pads on a side surface of at least one of the semiconductor devices.

18. The method of claim 17, wherein forming the one or more pads on the side surface of the at least one of the semiconductor devices comprises:
forming a semiconductor layer, wherein the semiconductor layer comprises one or more sealing structures;
forming one or more wires and one or more pads in the semiconductor layer, wherein the one or more wires are routed through and isolated from the one or more sealing structures, and the one or more wires are coupled to the one or more pads; and
removing a portion of the semiconductor layer to expose the one or more pads.

19. The method of claim 17, wherein forming the one or more pads on the side surface of the at least one of the semiconductor devices comprises:
forming one or more wires at a surface of a first semiconductor layer, wherein the one or more wires are routed through and isolated from one or more sealing structures in the first semiconductor layer;
forming a second semiconductor layer over the surface of the first semiconductor layer to form a stacked layer;
forming the one or more pads in the stacked layer, wherein the one or more wires are coupled to the one or more pads; and
removing a portion of the stacked layer to expose the one or more pads.

20. The method of claim 17, wherein:
the substrate comprises one or more pads;
forming the coupling structure on the substrate comprises bonding one or more of the second contacting structures of the coupling structure to the one or more pads of the substrate; and
bonding the coupling structure to the semiconductor devices comprises bonding one or more of the first contacting structures of the coupling structure to the one or more pads of the at least one of the semiconductor devices.
